(19) United States
(12) Patent Application Publication
(10) Pub. No.: US 2003/0052393 A1
(43) Pub. Date: Mar. 20, 2003

(54) Semiconductor device

(75) Inventors: Kazunari Michii, Tokyo (JP); Yasushi Kasatani, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/106,199

(22) Filed: Mar. 27, 2002

(30) Foreign Application Priority Data
Sep. 18, 2001 (JP) 2001-283084

(51) Int. Cl. H01L 23/02

(52) U.S. Cl. 257/678

(57) ABSTRACT

A semiconductor device comprises a package; one or a plurality of chips sealed in the package; and leads having inner parts electrically connected to the chip or the chips in the package, and outer parts extending outside the package. The package has an upper elevated part having a top surface, and terraced surfaces formed at a level below a level of the top surface. The leads are provided with joining parts to which leads included in another semiconductor device to be put on top of the package are to be bonded, respectively, on the terraced surface. The joining parts of the leads have a width greater than a width of other parts of the leads.

### BACKGROUND OF THE INVENTION

1. Field of the Invention

The present invention relates to a semiconductor device and, more particularly, to a semiconductor device formed by sealing one or a plurality of chips in a package and intended for forming a stacked semiconductor device or to a stacked semiconductor device formed by stacking semiconductor devices each formed by sealing one or a plurality of chips in a package.

2. Background Art

Efforts have been actively made in recent years for the miniaturization and functional improvement of semiconductor devices for electronic equipment to meet demands for the miniaturization and functional enhancement of electronic equipment. Various techniques that increase packaging density, for instance, by stacking a plurality of semiconductor packages each formed by sealing a chip in a package, have been proposed.

Some examples of conventional stacked semiconductor devices will be briefly described.

FIG. 10 shows a conventional stacked semiconductor device, such as disclosed in, for example, a Japanese Patent Application No. Hei 9-153561, in a schematic sectional view. Shown in FIG. 10 are chips 6, wires 7 electrically connecting electrode pads formed on the chips 6 to leads 33, semiconductor devices 31A and 31B, packages 32 sealing the chips 6 therein, upper surfaces 32a of the packages 32, and lower surfaces 32c of packages 32. Outer parts of the leads 33 project outside from the packages 32.

As shown in FIG. 10, the inner ends of the leads 33 of the semiconductor devices 31A and 31B are connected to the chips 6 by the wires 7. Each lead 33 projects outside from a part of the package 32 near the upper surface 32a of the package 32 and extends close along the side surface and the lower surface 32c of the package 32. The difference in level between the upper surface of the lead 33 on the side of the upper surface 32a of the package 32 and the upper surface 32a of the package 32 is very small and is smaller than the thickness of the lead 33.

In the stacked semiconductor device thus constructed, the upper semiconductor device 31B is placed on top of the lower semiconductor device 31A with end parts of the leads 33 extending along the lower surface 32c thereof lying over the outer parts of the leads 33 of the lower semiconductor device 31B extending on the side of the upper surface 32a, and bonding the leads 33 of the semiconductor devices 31A and 31B together to form the stacked semiconductor device.

FIG. 11 shows another conventional stacked semiconductor device, such as disclosed in a Japanese Patent Application No. Hei 8-139270, in a schematic sectional view. Shown in FIG. 11 are semiconductor devices 41A and 41B, packages 42 sealing chips therein, and leads 43 connected to the chips in the packages 42 and projecting outside form the packages 43.

As shown in FIG. 11, outer parts of the leads 43 of the semiconductor devices 41A and 41B projecting outside from the packages 42 do not extend close along the packages 42, and outer end parts extending outside corresponding to the lower surfaces of the packages 42 of the leads 43 are bent down. A plane including the lower ends of the outer end parts of the leads 43 is spaced a sufficient distance apart from a plane including the lower surface of the package 42.

In the stacked semiconductor device thus constructed, the upper semiconductor device 41B is disposed over the lower semiconductor device 41A with the lower ends of the outer end parts of the leads 43 thereof in contact with the leads 43 of the lower semiconductor device 41A, and the leads 43 of the semiconductor devices 41A and 41B are bonded together to stack the semiconductor devices 41A and 41B.

Those conventional stacked semiconductor devices have various problems. The stacked semiconductor device shown in FIG. 10 has a first problem that the visual inspection of the joints of the leads of the stacked semiconductor device shown in FIG. 10 is difficult, and work for repairing a faulty joint of the leads is difficult. Generally, the joints of the leads of the stacked semiconductor device are inspected visually for faulty joints due to faulty soldering to insure the satisfactory quality of short-term and long-term operations. If a faulty joint formed by faulty soldering or the like is found, the faulty joint is repaired by using a soldering iron or the like.

Since the upper and the lower semiconductor device of the stacked semiconductor device shown in FIG. 10 are stacked virtually in close contact with each other and hence the visual inspection of the entire peripheral parts of the joints of the leads is difficult, and it is difficult to insert a soldering iron in a narrow gap between the semiconductor devices for repairing.

The stacked semiconductor device shown in FIG. 11 has a second problem that, when the semiconductor devices are stacked to form the stacked semiconductor device shown in FIG. 11, sometimes, the outer ends of the plurality of leads are arranged irregularly at different levels and it is difficult to bond the leads satisfactorily together.

The leads of the stacked semiconductor device shown in FIG. 11 extend in a cantilever-fashion and each lead has two bends. Therefore, it is difficult to align the ends of all the plurality of leads in a plane. Thus, it is very difficult to bond the floating, irregularly arranged end parts of the leads of the upper and the lower semiconductor device satisfactorily together.

The stacked semiconductor device shown in FIG. 10 has an advantage over the stacked semiconductor device shown in FIG. 11 in respect of the second problem. Since the leads of the stacked semiconductor device shown in FIG. 10 are not floating and extend along the surfaces of the packages, and the end parts to be bonded of the leads are secured to the packages, the corresponding end parts can be comparatively satisfactorily bonded together.

The stacked semiconductor device shown in FIG. 11 has an advantage over the stacked semiconductor device shown in FIG. 10 in respect of the first problem. Since the end parts to be bonded together of the leads of the stacked semiconductor shown in FIG. 11 are not in close contact with the packages, work for the visual inspection of the joints of the leads and repairing work is comparatively easy.

A third problem common to the stacked semiconductor devices shown in FIGS. 10 and 11 is that the end parts to be bonded together of the leads cannot be bonded together by a sufficient bond strength if the upper and the lower semiconductor device are not stacked correctly. Sometimes, the upper semiconductor device cannot be put on the lower semiconductor device in a correct position if a stacking machine for stacking the semiconductor devices operates in a low positioning accuracy. If the upper semiconductor device is not put on the lower semiconductor device correctly, the end parts of the plurality leads of the upper semiconductor device are displaced relative to the corresponding end parts of the leads of the lower semiconductor device. Consequently, the area of the bonding surfaces of the corresponding end parts of the leads is reduced and hence the bond strength is reduced.

### SUMMARY OF THE INVENTION

The present invention has been made to solve the foregoing problems and it is therefore an object of the present invention to provide a reliable semiconductor device for forming a stacked semiconductor device, capable of facilitating the visual inspection of the joints of leads and the repair of faulty joints, provided with leads capable of being highly satisfactorily bonded to those of another semiconductor device by high bonding strength even if the semiconductor device is displaced from a correct position relative to another semiconductor device.

According to one aspect of the present invention, a semiconductor device comprises a package; one or a plurality of chips sealed in the package; and leads having inner parts electrically connected to the chip or the chips in the package, and outer parts extending outside the package. The package has an upper elevated part having a top surface, and terraced surfaces formed at a level below a level of the top surface. The leads are provided with joining parts to which leads included in another semiconductor device to be put on top of the package are to be bonded, respectively, on the terraced surface. The joining parts of the leads have a width greater than a width of other parts of the leads.

Other and further objects, features and advantages of the invention will appear more fully from the following description.

### BRIEF DESCRIPTION OF THE DRAWINGS

FIG. 1 is a top view of a first semiconductor device included in the stacked semiconductor device in the first embodiment;

FIG. 2 is a sectional view taken on line A-A in FIG. 1;

FIG. 3 is a schematic sectional view of the second semiconductor device to be placed on top of the first semiconductor device 1 shown in FIGS. 1 and 2;

FIG. 4 is a schematic sectional view taken on line B-B in FIG. 3;

FIG. 5 is a schematic top view of the stacked semiconductor device in the first embodiment;

FIG. 6 is a schematic sectional view taken on line C-C in FIG. 5;

FIG. 7 is a schematic perspective view of a part around the joining part 3a of the first semiconductor device 1;

FIG. 8 is a schematic sectional view of the stacked semiconductor device in the second embodiment according to the present invention;

FIG. 9 is a schematic perspective view of a part around joints of leads in the stacked semiconductor device shown in FIG. 8;

FIG. 10 shows a conventional stacked semiconductor device in a schematic sectional view;

FIG. 11 shows another conventional stacked semiconductor device in a schematic sectional view.

### DETAILED DESCRIPTION OF THE PREFERRED EMBODIMENTS

Preferred embodiments of the present invention will be described with reference to the accompanying drawings, in which the same or like parts are denoted by the same reference characters and the duplicate description thereof will be omitted.

First Embodiment

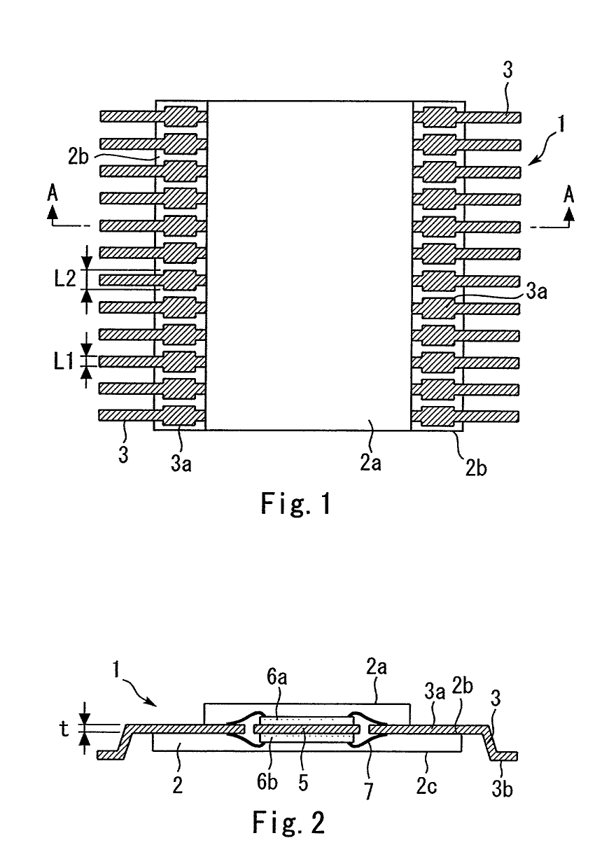

A stacked semiconductor device according to a first embodiment of the present invention will be described with reference to FIGS. 1 to 7. FIG. 1 is a top view of a first semiconductor device included in the stacked semiconductor device in the first embodiment and FIG. 2 is a sectional view taken on line A-A in FIG. 1.

Referring to FIGS. 1 and 2, there are shown a first semiconductor device 1, a package 2 of a resin or the like sealing chip 6a and 6b therein, a top surface 2a of the package 2, terraced surfaces 2b of the package 2, a bottom surface 2c of the package 2, leads 3 extending through the package 2 and projecting outside from the package 2, joining parts 3a of the leads 3 to which leads of one other semiconductor device put on the first semiconductor device 1 are bonded, end parts 3b of the leads 3 to be bonded to the leads of a semiconductor device underlying the semiconductor device 1, a die pad 5, chips 6a and 6b bonded to the opposite surfaces of the die pad 5, respectively, and wires 7 electrically connecting electrode pads formed on the chips 6a and 6b to the leads 3.

The package 2 has a central elevated part having the top surface 2a and the terraced surfaces 2b. The terraced surfaces 2b extend at the both ends of the elevated part having the top surface 2a at a level lower than that of the top surface 2a. As shown in FIG. 1, the package 2 has a cross section having a middle protrusion. The difference in level between the top surface 2a and the terraced surfaces 2b is greater than the thickness t of the leads 3.

As shown in FIG. 2, the leads 3 have inner parts connected to the electrode pads of the chips 6a and 6b by the wires 7, respectively, and outer parts extending on the terraced surfaces 2b of the package 2. The outer part of each lead 3 is bent at two bends such that an end part thereof extends away from the package 2 at a level below that of the bottom surface 2c of the package 2.

As shown in FIG. 1, the joining parts 3a are formed integrally with parts extending on the terraced surfaces 2b of the package 2 of the leads 3 in a width L2 greater than the width L1 of parts of the lead 3 other than the joining parts 3a. The leads 3 are formed by, for example, press working. When stacking the first semiconductor device 1 and a second semiconductor device, end parts of the leads of the second semiconductor device are bonded to the joining parts 3a having an increased area.

The first semiconductor device 1 is fabricated by the following processes. The second chip 6b obtained by dicing a wafer provided with integrated circuits is bonded to one of the surfaces of the die pad 5 formed in a leadframe. The leads 3 of the leadframe are connected to the electrode pads of the second chip 6b by the wires 7 by wire bonding. Subsequently, the leadframe is inverted and the first chip 6a is bonded to the other surface of the die pad 5. Then, the leads 3 of the leadframe are connected to the electrode pads of the first chip 6a by the wires 7 by wire bonding. The assembly of the chips 6a and 6b, the leadframe and the wires 7 thus formed is placed in a cavity of a mold having a parting plane corresponding to the terraced surfaces 2b of the package 2, and the package 2 is molded. Subsequently, the leadframe is subjected to a cutting process, and the leads 3 are bent in the desired shape to complete the first semiconductor device 1.

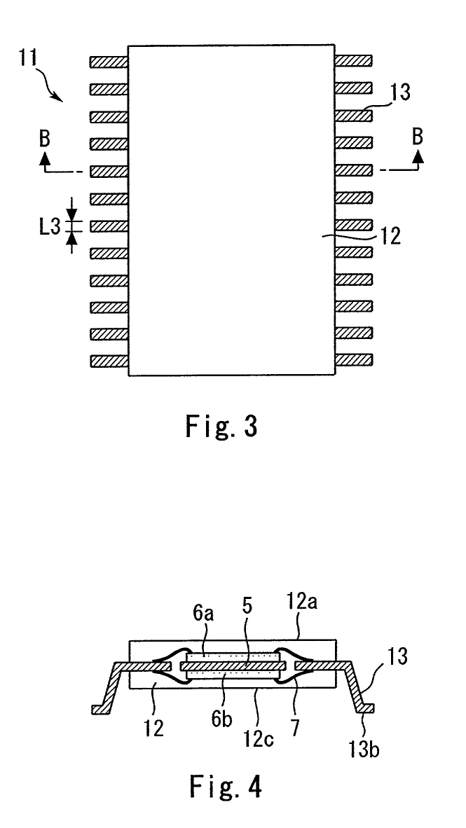

The second semiconductor device to be placed on top of the first semiconductor device 1 will be described with reference to FIGS. 3 and 4. FIG. 3 is a schematic sectional view of the second semiconductor device to be placed on top of the first semiconductor device 1 shown in FIGS. 1 and 2. FIG. 4 is a schematic sectional view taken on line B-B in FIG. 3.

Referring to FIGS. 3 and 4, there are shown a second semiconductor device 11, a package 12, a top surface 12a of the package 12, a bottom surface 12c of the package 12, leads 13, end parts 13b to be bonded to the joining parts 3a of the leads 3 of the first semiconductor device 1, a die pad 5, chips 6a and 6b, and wires 7.

As shown in FIG. 4, the leads 13 have inner parts connected to the electrode pads of the chips 6a and 6b by the wires 7, respectively, and outer parts projecting from the side surfaces of the package 12. The outer part of each lead 13 is bent down at a part near the side surface of the package 12 and is bent laterally at an end part such that an end part 13b thereof extends away from the package 12 at a level below that of the bottom surface 12c of the package 12. The difference in level between the bottom surface 12c of the package 12 and the end part 13b of the lead 13 is sufficiently large. As shown in FIG. 3, the leads 13 of the second semiconductor device 11 have a substantially uniform width L3 smaller than the width L2 of the joining parts 3a of the leads 3 of the first semiconductor device 1 shown in FIGS. 1 and 2.

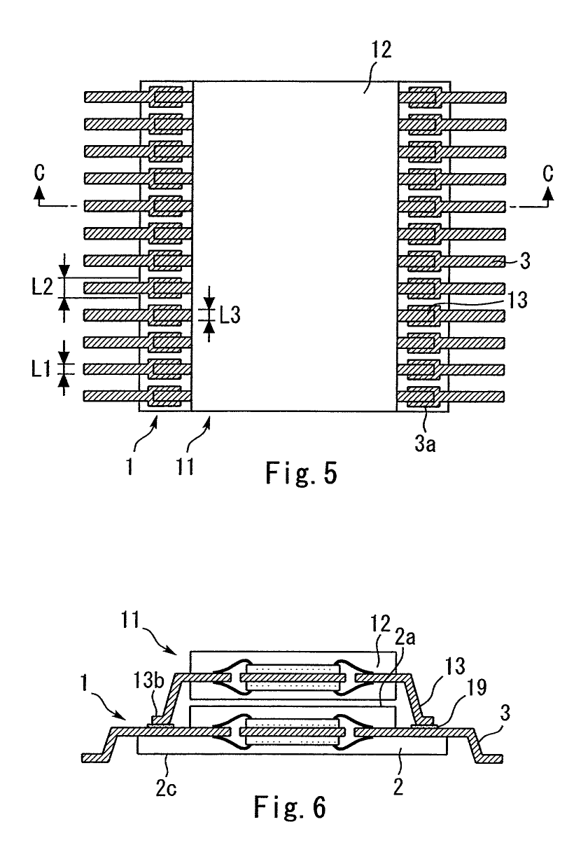

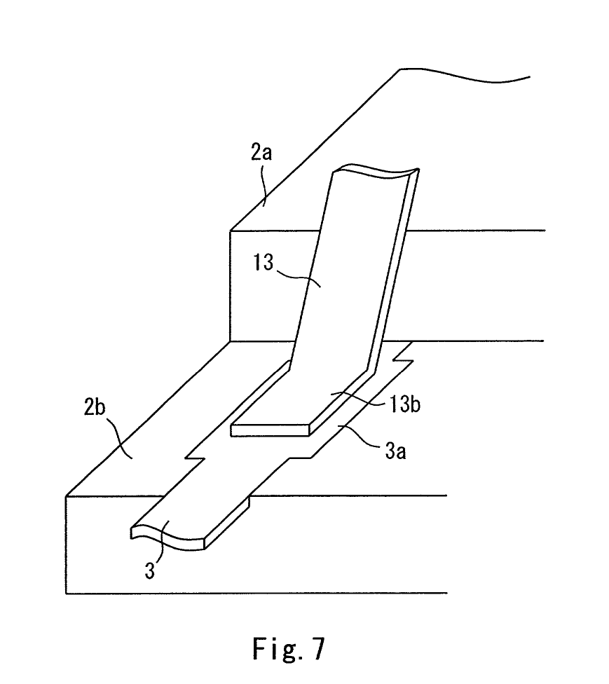

The stacked semiconductor device in the first embodiment constructed by stacking the two semiconductor devices 1 and 11 will be described with reference to FIGS. 5 to 7. FIG. 5 is a schematic top view of the stacked semiconductor device in the first embodiment, and FIG. 6 is a schematic sectional view taken on line C-C in FIG. 5. FIG. 7 is a schematic perspective view of a part around the joining part 3a of the first semiconductor device 1.

As shown in FIG. 6, the second semiconductor device 11 shown in FIGS. 3 and 4 is put on the first semiconductor device 1 shown in FIGS. 1 and 2. Solder paste layers 19 are formed on the joining parts 3a of the first semiconductor device 1. The end parts 13b of the leads 13 of the second semiconductor device 11 are aligned with the corresponding joining parts 3a of the first semiconductor device 1, and then the end parts 13b are brought into contact with the corresponding joining parts 3a. Then, the end parts 13b are bonded to the joining parts 3a by reflow soldering.

As shown in FIGS. 5 and 7, the width L2 of the joining parts 3a of the first semiconductor device 1 is sufficiently greater than the width L3 of the end parts 13b of the leads 13 of the second semiconductor device 11. Accordingly, the end parts 13b are not displaced off the joining parts 3a and the end parts 13b are fully bonded to the joining parts 3a, respectively, even if the second semiconductor device 11 is disposed in an incorrect position relative to the first semiconductor device 1.

As shown in FIGS. 6 and 7, the joints of the joining parts 3a and the end parts 13b are formed on an open surface of the stacked semiconductor device. Therefore, the entire peripheries of all the joints can be comparatively easily inspected by visual inspection, and, if a faulty joint is found, the faulty joint can be easily repaired with a repairing tool. Thus, defects in the stacked semiconductor device can be found and defective stacked semiconductor devices can be reduced, and the yield of the stacked semiconductor devices, i.e., multiple-chip packages, can be improved.

As shown in FIGS. 6 and 7, most part of each lead 3 of the first semiconductor device 1 extends on the terraced surfaces 2b, and only a short part of the same extends in a cantilever-fashion. Thus, the end parts 3b of the leads 3 of the first semiconductor device 1 can be arranged in comparatively small irregularity.

When the second semiconductor device 11 is put on top of the first semiconductor device 1, the joining parts 3a are not displaced even if the end parts 13b are pressed against the joining parts 3a of the leads 3 of the first semiconductor device 1 because the joining parts 3a are held fixedly in place on the terraced surfaces 2b of the package 2. Thus, the end parts 13b can be comparatively easily bonded to the joining parts 3a.

As apparent from the foregoing description, the joints of the leads of the first and the second semiconductor device of the stacked semiconductor device in the first embodiment can be comparatively easily inspected by visual inspection, if any faulty joint is found, the faulty joint can be easily repaired, leads can be satisfactorily bonded together, and the leads can be bonded together by a sufficient bond strength even if the first and the second semiconductor device are not stacked correctly. Thus, the stacked semiconductor device in the first embodiment performs its intended function with high reliability.

Although the invention has been described as applied to the stacked semiconductor device formed by stacking the two semiconductor devices 1 and 11, the invention is applicable to stacked semiconductor devices formed by stacking more than two semiconductor devices. In a stacked semiconductor device formed by stacking more than two semiconductor devices, all the component semiconductor devices are formed in construction similar to that of the first semiconductor device 1 of the stacked semiconductor device in the first embodiment. In a stacked semiconductor device of construction similar to that of the stacked semiconductor device in the first embodiment, formed by stacking more than two semiconductor devices, the upper semiconductor devices have sizes smaller than those of the lower semiconductor devices due to the construction of the stacked semiconductor device.

Although each of the component semiconductor devices of the stacked semiconductor device in the first embodiment is a multiple-chip semiconductor device provided with the two chips 6a and 6b sealed in the package 2 or 12, each of the component semiconductor devices may be a single-chip semiconductor device provided with a single chip.

Although the plurality of leads 3 are distributed equally to the both ends (two sides) of the package 2 in the first embodiment, the leads 3 may be arranged in any suitable arrangement. For example, the leads may be arranged on four terraced surfaces extending along the periphery (four sides) of a package, and the leads may be provided with joining parts in parts thereof extending on the terraced surfaces of the package.

Second Embodiment

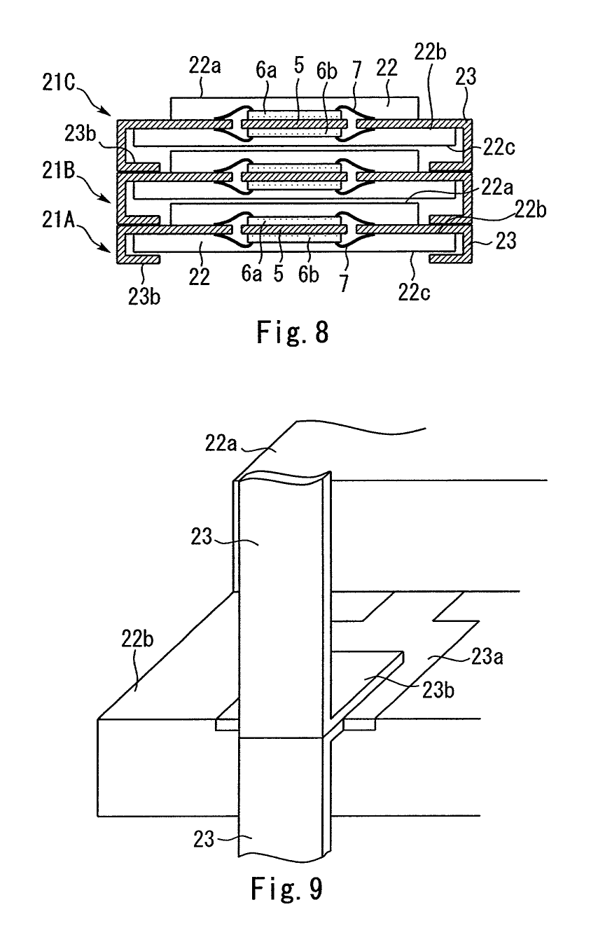

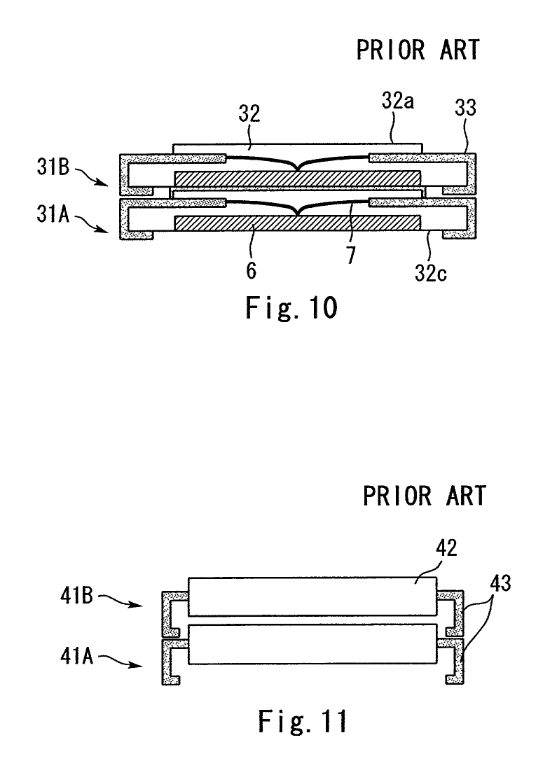

A stacked semiconductor device in a second embodiment according to the present invention will be described with reference to FIGS. 8 and 9. FIG. 8 is a schematic sectional view of the stacked semiconductor device in the second embodiment according to the present invention, and FIG. 9 is a schematic perspective view of a part around joints of leads in the stacked semiconductor device shown in FIG. 8. The stacked semiconductor device in the second embodiment differs from the stacked semiconductor device in the first embodiment principally in that the stacked semiconductor device in the second embodiment includes three component semiconductor devices of the same configuration, and end parts of leads are bent so as to extend inward.

Shown in FIGS. 8 and 9 are semiconductor devices 21A, 21B and 21C, packages 22, a top surface 22a of each package 22, terraced surfaces 22b of each package 22, a bottom surface 22c of each package 22, leads 23, joining parts 23a of the leads 23, and end parts 23b of the leads 23.

The semiconductor devices 21A, 21B and 21C are substantially the same in construction. The package 22 has a central elevated part having the top surface 22a, and the terraced surfaces 22b extend on the both ends of the elevated part having the top surface 22a at a level lower than that of the top surface 22a. The difference in level between the top surface 22a and the terraced surfaces 22b is far greater than the thickness of the leads 23.

As shown in FIG. 8, the leads 23 have inner parts connected to the electrode pads of chips 6a and 6b by wires 7, respectively, and outer parts extending on the terraced surfaces 22b of the package 22. The outer part of each lead 23 extends on the terraced surface 22b, and is bent at two bends such that the end part 23b thereof extend toward an inner part of the bottom surface 22c at a level below that of the bottom surface 22c of the package 22. Thus, the end parts 23b of the leads 23 are bent in a shape substantially resembling the letter U.

As shown in FIG. 9, the joining part 23a of each lead 23 is formed integrally with the part extending on the terraced surface 22b of the package 22 of the lead 23. The joining parts 23a, similarly to those of the first embodiment, have a width greater than that of other parts of the lead 23.

The three semiconductor devices 21A, 21B and 21C are stacked as shown in FIGS. 8 and 9. Solder paste layers are formed on the joining parts 23a of the first semiconductor device 21A. The end parts 23b of the leads 23 of the second semiconductor device 21B overlying the first semiconductor device 21A are bonded to the joining parts 23a of the first semiconductor device 21A by reflow soldering. Similarly, solder paste layers are formed in the joining parts 23a of the second semiconductor device 21B, and the end parts 23b of the leads 23 of the third semiconductor device 21C overlying the second semiconductor device 21B are bonded to the joining parts 23a of the second semiconductor device 21B by reflow soldering.

As apparent form the foregoing description, the width of the joining parts 23a of the leads 23 is sufficiently greater than that of other parts of the leads 23. Accordingly, the end parts 23b are not displaced off the joining parts 23a and the end parts 23b are fully bonded to the joining parts 23a, respectively, even if the upper semiconductor device 21B or 21C is disposed in an incorrect position relative to the under semiconductor device 21A or 21B.

As shown in FIGS. 8 and 9, the joints of the joining parts 23a and the end parts 23b are formed on an open surface of the stacked semiconductor device. Therefore, the entire peripheries of all the joints can be comparatively easily inspected by visual inspection, and, if a faulty joint is found, the faulty joint can be easily repaired with a repairing tool.

As shown in FIGS. 8 and 9, the leads 23 of the semiconductor devices 21A, 21B and 21C, similarly to those of the first embodiment, are formed and held on the package 22 such that the end parts 23b are arranged in comparatively small irregularity.

Since the end parts 23b are bonded to the stable joining parts 23a fixedly held on the terraced surfaces 22b of the package 22, the end parts 23b can be securely and comparatively easily bonded to the joining parts 23a.

As apparent from the foregoing description, the joints of the leads, similarly to those of the first embodiment, can be comparatively easily inspected by visual inspection, if any faulty joint is found, the faulty joint can be easily repaired, leads can be satisfactorily bonded together, and the leads can be bonded together by a sufficient bond strength even if the semiconductor device are not stacked correctly. Thus, the stacked semiconductor device performs its intended function with high reliability. Since the stacked semiconductor device in the second embodiment is formed by stacking the semiconductor devices 21A, 21B and 21C of the same construction, the number of the component semiconductor devices can be increased substantially without any restrictions.

In the semiconductor device of the present invention, the upper elevated part having the top surface may be formed in a central part of an upper surface of the package, and the terraced surfaces may be formed at both ends of the elevated part or in a peripheral part of the upper surface of the package.

In the semiconductor device, a difference in level between the top surface of the elevated part and the terraced surfaces may be greater than thickness of the leads.

In the semiconductor device, end parts of the outer parts of the leads may extend away from the package at a level below a level of a bottom surface of the package.

In the semiconductor device, end parts of the outer parts of the leads may extend toward an inner part of the bottom surface of the package at a level below a level of the bottom surface of the package.

A stacked semiconductor device may be formed by stacking a plurality of semiconductor devices similar to the above semiconductor device.

A stacked semiconductor device may be formed by putting one other semiconductor device on top of the above semiconductor device with end parts of leads included in the other semiconductor bonded to the joining parts of the semiconductor device underlying the other semiconductor.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-283084, filed on Sep. 18, 2001 including specification, claims, drawings and summary, on which the Convention priority of the present application is based, are incorporated herein by reference in its entirety.

What is claimed is:

1. A semiconductor device comprising:
a package;
one or a plurality of chips sealed in said package; and
leads having inner parts electrically connected to the chip or the chips in said package, and outer parts extending outside said package;
wherein said package has an upper elevated part having a top surface, and terraced surfaces formed at a level below a level of the top surface,
said leads are provided with joining parts to which leads included in another semiconductor device to be put on top of said package are to be bonded, respectively, on said terraced surface, and
said joining parts of said leads have a width greater than a width of other parts of said leads.

2. The semiconductor device according to claim 1, wherein said upper elevated part having the top surface is formed in a central part of an upper surface of said package, and said terraced surfaces are formed at both ends of said elevated part or in a peripheral part of the upper surface of said package.

3. The semiconductor device according to claim 1, wherein a difference in level between the top surface of said elevated part and said terraced surfaces is greater than thickness of said leads.

4. The semiconductor device according to claim 1, wherein end parts of said outer parts of said leads extend away from said package at a level below a level of a bottom surface of said package.

5. The semiconductor device according to claim 1, wherein end parts of said outer parts of said leads extend toward an inner part of the bottom surface of said package at a level below a level of the bottom surface of said package.

6. A stacked semiconductor device formed by stacking a plurality of semiconductor devices, each of said plurality of semiconductor devices comprising:
a package;
one or a plurality of chips sealed in said package; and
leads having inner parts electrically connected to the chip or the chips in said package, and outer parts extending outside said package;
wherein said package has an upper elevated part having a top surface, and terraced surfaces formed at a level below a level of the top surface,
said leads are provided with joining parts to which leads included in another semiconductor device to be put on top of said package are to be bonded, respectively, on said terraced surface,
said joining parts of said leads have a width greater than a width of other parts of said leads, and
end parts of said outer parts of said leads extend toward an inner part of the bottom surface of said package at a level below a level of the bottom surface of said package.

7. A stacked semiconductor device formed by stacking a plurality of semiconductor devices, each of said plurality of semiconductor devices comprising: a package; one or a plurality of chips sealed in said package; and leads having inner parts electrically connected to the chip or the chips in said package, and outer parts extending outside said package; wherein said package has an upper elevated part having a top surface, and terraced surfaces formed at a level below a level of the top surface, said leads are provided with joining parts to which leads included in another semiconductor device to be put on top of said package are to be bonded, respectively, on said terraced surface, and said joining parts of said leads have a width greater than a width of other parts of said leads,
wherein the end parts of said leads in one semiconductor device are bonded respectively to said joining parts of the other semiconductor device.
